(19) United States
(12) Patent Application Publication
(10) Pub. No.: US 2005/0062619 A1
(43) Pub. Date: Mar. 24, 2005

(54) Keypad for an electronic device

(76) Inventor: Roger J. Jellicoe, Woodstock, IL (US)

Correspondence Address: MOTOROLA INC, 600 NORTH US HIGHWAY 45, ROOM AS437, LIBERTYVILLE, IL, 60048-5343, US

(21) Appl. No.: 10/668,486

(22) Filed: Sep. 23, 2003

(51) Int. Cl. H03M 11/00; H03K 17/94

(52) U.S. Cl. 341/22

(57) ABSTRACT

A keypad (110) for an electronic device (100) includes nested telephony keys (115) having both an indented edge and a protruded edge in a substantially planar surface. The keys (151, 152, 153, 154, 155, 156, 157, 158, 159, 161, 162, 163) have alphanumeric telephony labels consistent with the ISO Standard keypad. A priority routine enters a character of a first alphanumeric label when a switch under a key is held for shorter than a first toggle period, and the priority routine enters a character of a second alphanumeric label when the switch is held for longer than the first toggle period.

### FIELD OF THE DISCLOSURE

This disclosure relates generally to reduced keypads for devices such as fixed telephones, mobile telephones, personal digital assistants (PDAs), and remote controllers.

### BACKGROUND OF THE DISCLOSURE

A reduced keypad for a telephone, PDA, remote controller, or similar device typically has between twelve and twenty keys for controlling the operation of the device. The keys generally include: number keys “0”-“9”; telephony keys and “#”; and keys for additional functions such as “menu”, “cancel”, “cursor up”, “cursor down,” “cursor right,” “cursor left,” and “select”.

There is an International Standards Organisation (ISO) Standard for reduced keypads where number keys are associated with certain groups of three letters of the alphabet: ISO/IEC 9995-8:1994 and ITU-T Recommendation E.161 Option A. A prior art ISO Standard keypad arrangement is illustrated at FIG. 7. According to the ISO Standard, the “2” key is associated with the number “2” and the letters “A”, “B,” and “C.” Likewise the “3” key is associated with the number “3” and the letters “DEF” and so on until the “9” key, which is associated with the number “9” and the letters “WXY”. In addition to the number keys, the ISO Standard has telephony keys “*” and “#”. The ISO Standard requires that the keys be arranged in four rows of three keys.

Known, and natural, extensions of the ISO Standard are to include missing letter Q on the “7” key and missing letter Z on the “9” key or further incorporate characters belonging to languages other than English. For example, German and French characters can each be associated with a telephony key. Also not part of the ISO Standard, sometimes the “1” key is associated with a space/blank and punctuation marks, and occasionally the “0” key is associated with special symbols.

In order to increase the number of functions available through a device (or maintain a constant number of functions in light of decreasing device size), manufacturers generally increase the number of keys in the reduced keypad. Often this includes reducing the surface area of keys and/or reducing the distance between keys. As a key's surface area and/or the distance between keys decreases, however, a key becomes harder to press accurately. Users with large or insensitive fingers, users with impaired fine motor coordination, or users wearing gloves often suffer from inaccurate keypresses on such reduced keypads. To compound the problem, the smaller area on key surfaces and between keys result in small labels for the keys that may be difficult to read.

In addition to increasing the number of keys in a reduced keypad, often several keys in the reduced keypad are associated with multiple functions and/or meanings in order to enable the increased number of features and functions of the device. Commonly, the reduced keypad functions as an alphanumeric keypad for features such as messaging and phonebook, where both letters and numbers are entered from the reduced keypad.

Typically, alphanumeric characters are selected by repeatedly pressing an associated key and cycling through the choices until a pause (or selection of another key) by the user indicates a choice has been made. For example, if a user presses the “2” key once, the letter “A” is entered, if the user presses the “2” key twice, the letter “B” is entered, and if the user presses the “2” key three times, the letter “C” is entered. This scheme is known as multi-press (or multi-tap) input and provides a letter-by-letter data entry method. A disadvantage of the multi-press input scheme is that up to four taps may be required to enter a letter, which results in time-consuming data entry.

An alternative to multi-press input is a two-press input scheme. A first keypress specifies a letter group and a second keypress relates to the place of the desired letter in the group. Thus, first pressing the “5” key for the character group “JKL5” and then pressing the “2” key will result in the entry of a “K”. Although this two-press input scheme eliminates the three and four presses contemplated in the multi-press input scheme, it requires at least two presses to enter a letter.

Another letter-by-letter input scheme involves predicting a next letter of a word based on any previously entered letters and the present keypress. For example, if “F” and “O” have already been entered, pressing the “7” key may result in an “R” on the display. Additional presses of the “7” key will cycle through the characters “S,” “P,” and “7”. This is an improvement on the multi-press and two-press input schemes but still usually requires more than one press per letter of a word.

In any of the letter-by-letter input schemes, the reduced keypad generally has a default timeout period so that a pause in keypresses longer than the timeout period will be interpreted as a confirmation of the most recent keypress. Confirmation of an input by selection of a further, different key (including a dedicated confirmation key) is also possible under the multi-press input scheme.

In contrast to the letter-by-letter input schemes, there are also word-by-word input schemes where a user presses just once on each key corresponding to the group of letters containing the desired letter until a word is complete. A processor within the device accesses a dictionary of complete words and suggests a list of possible complete words corresponding to the numerical sequence entered. A selection key is used to cycle through each of the possible complete words. The single-press approach, however, is not useful for entry of words not found in the dictionary (usually proper names, abbreviations, and specialized terms). When the dictionary does not contain the intended word, text entry may revert to one of the letter-by-letter schemes or to an error-correction mode. Ultimate text entry of the intended word may then require more keystrokes than if the user had started with a letter-by-letter scheme.

Thus, there is a desire for a reduced keypad that facilitates alphanumeric character entry without miniaturization of key surface areas and distances between keys. There is also a desire for a reduced keypad that is consistent with the ISO standard such that only minor learning or practice is required to enter alphanumeric characters.

The various aspects, features and advantages of the disclosure will become more fully apparent to those having ordinary skill in the art upon careful consideration of the following Drawings and accompanying Detailed Description.

### BRIEF DESCRIPTION OF THE DRAWINGS

FIG. 1 shows a keypad implemented in an electronic device according to a first preferred embodiment.

FIG. 2 shows an exploded view of the keypad shown in FIG. 1.

FIG. 3 shows details of a telephony key shown in FIG. 1.

FIG. 4 shows an alternate telephony key according to a second preferred embodiment.

FIG. 5 shows a flow chart for character entry, with a priority on numeric entry, using the keypad shown in FIG. 1.

FIG. 6 shows a flow chart for character entry, with a priority on non-numeric entry, using the keypad shown in FIG. 1.

FIG. 7 shows a prior art ISO Standard keypad arrangement.

### DETAILED DESCRIPTION OF THE PREFERRED EMBODIMENTS

A keypad for an electronic device includes nested telephony keys having both a protruded edge and an indented edge in a substantially planar surface. The keys have alphanumeric telephony labels consistent with the ISO Standard keypad. A priority routine enters a character of a first alphanumeric label when a switch under a key is held for shorter than a first toggle period, and the priority routine enters a character of a second alphanumeric label when the switch is held for longer than the first toggle period. When the priority routine favors numbers, numbers are entered when the switch is held for shorter than the first toggle period while non-numeric characters are entered when the switch is held for longer than the first toggle period. When the priority routine favors non-numeric characters, non-numeric characters are entered when the switch is held for shorter than the first toggle period while numbers are entered when the switch is held for longer than the first toggle period. At least one additional toggle period is provided so that further characters can be entered using the same key when the switch is held for longer than the additional toggle period.

The keypad provides an ergonomically efficient key shape and spacing. This keypad also facilitates alphanumeric character entry by providing priority routines that allow one key with multiple switches to quickly enter numeric and non-numeric characters.

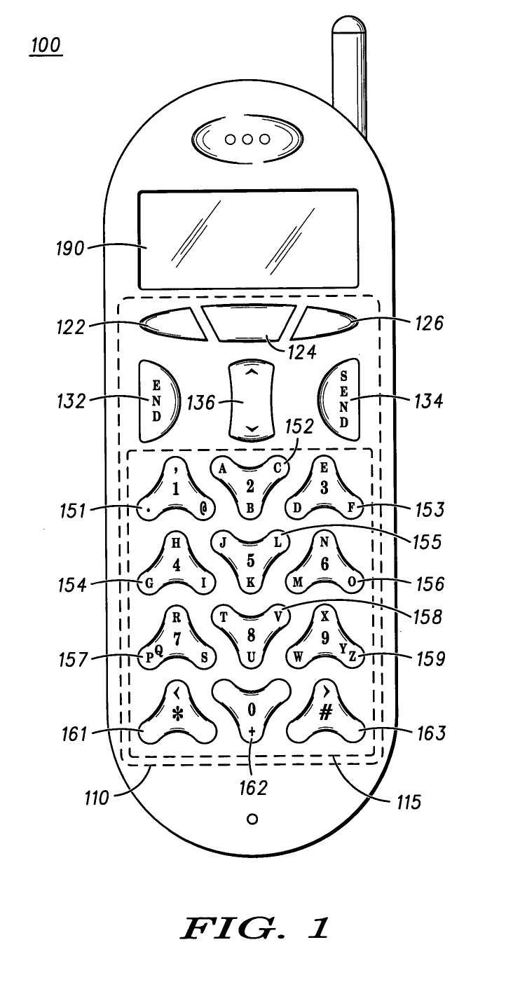

FIG. 1 shows a keypad 110 implemented in an electronic device 100 according to a first preferred embodiment. In this embodiment, the electronic device 100 is a mobile telephone; however, many other electronic devices such as fixed telephones, personal digital assistants (PDAs), and remote controllers can use the keypad. The keypad 110 includes a plurality of keys on a substantially planar region. These keys may have different shapes, sizes, features, and functions. For example, softkeys 122, 124, 126 have different functions depending on their labels according to the screen 190. END key 132 and SEND key 134 perform common telephony functions for the mobile telephone, and UP/DOWN key 136 is a bidirectional key that allows both up and down movement of a cursor on the screen 190.

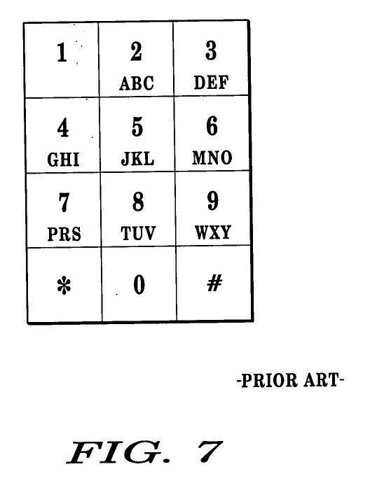

The keypad 110 also includes telephony keys 115 with an arrangement consistent with the ISO Standard keypad arrangement shown in FIG. 7. Key 151 is labeled with the number “1” as well as several punctuation marks. In this first preferred embodiment, the punctuation marks are period ”.”, comma ”,”, and the at symbol “@”. Key 152 is labeled with the number “2” and the letters “A”, “B,” and “C.” Likewise, key 153 is associated with the number “3” and the letters “DEF” and so on through keys 154, 155, 156, 157, 158, until key 159, which is associated with the number “9” and the letters “WXYZ”. Key 161 is labeled with telephony symbol “*” and a backspace sign, key 162 is labeled with the number “0” and the plus “+” sign, and key 163 is labeled with telephony symbol “#” and a space sign. The labels are shown on the keys themselves in this embodiment. The labels, however, could be adjacent to the keys and still be readily associated with the appropriate key.

Each of the telephony keys 151, 152, 153, 154, 155, 156, 157, 158, 159, 161, 162, 163 has a similar shape, which shall be described in detail. Having the same shape makes manufacture of the keypad simpler due to fewer unique parts; however, each key does not require the same shape in order for the keypad to demonstrate benefits.

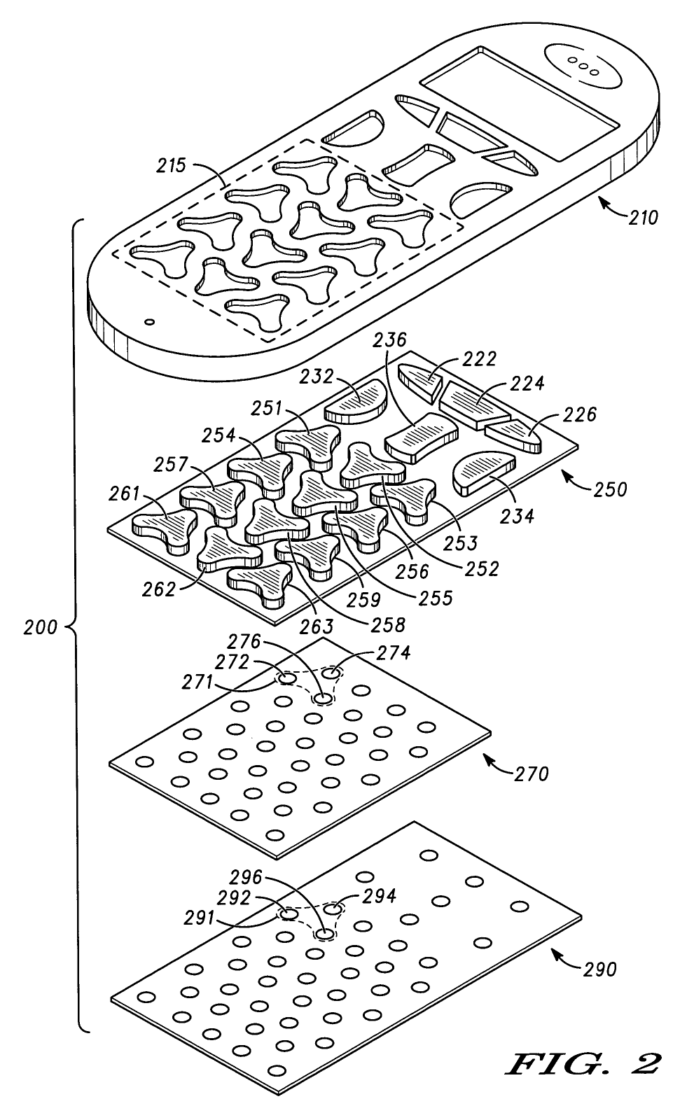

FIG. 2 shows an exploded view 200 of the keypad 110 shown in FIG. 1. Layer 210 shows a keypad portion of a plastic housing of the electronic device 100 shown in FIG. 1. Layer 250 shows key covers 222, 224, 226, 232, 234, 236 as well as key covers for telephony keys 251, 252, 253, 254, 255, 256, 257, 258, 259, 261, 262, and 263. Preferably, the key covers are constructed from a soft, pliable material such as silicone. In another embodiment, the key covers are constructed of a rigid material such as metal or hard plastic mounted on and held in an aligned position by a soft pliable membrane or webbing.

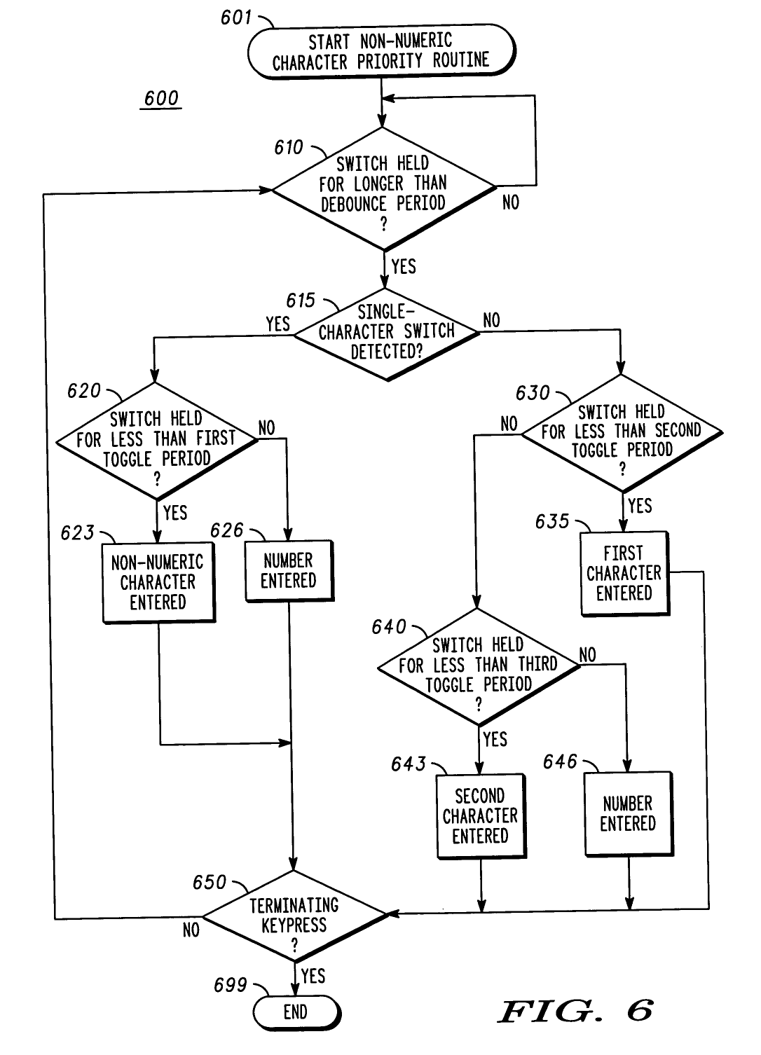

Each telephony key is aligned over three switches in layers 270 and 290. For example, key cover 251 is aligned over three switch domes 272, 274, 276 in region 271. Pressing an apex of a key cover 251 causes the switch dome 274 underneath the apex to close against the circuit board contact 294. Similarly, pressing the left foot of key cover 251 causes the switch dome 272 underneath the left foot to close against the circuit board contact 292 while pressing the right foot of key cover 251 causes the switch 276 underneath the right foot to close against the circuit board contact 296. Preferably, the switches in layers 270 and 290 are in a substantially hexagonal packing arrangement, which is the most efficient sphere packing arrangement. Other switch geometries, such as square packing, are possible but less efficient. As will be explained with reference to FIG. 5 and FIG. 6, a user can enter numeric and non-numeric characters using the keypad 110 depending on the entry mode of the device and how long a particular switch is closed.

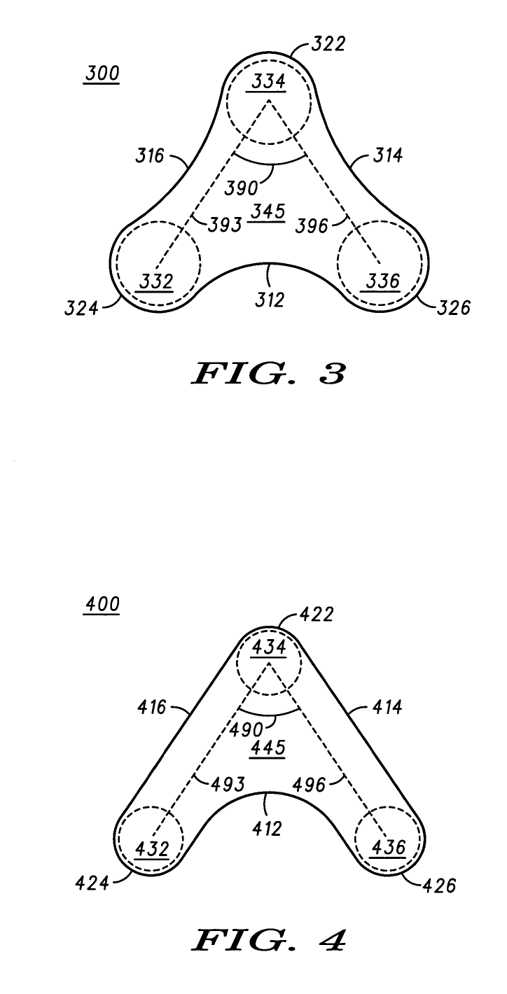

FIG. 3 shows details of a telephony key 300 shown in FIG. 1. Depending on its orientation, the telephony key 300 could be one of the twelve telephony keys 151, 152, 153, 154, 155, 156, 157, 158, 159, 161, 162, 163 shown in FIG. 1. In the orientation shown, the key 300 has an indented bottom edge 312 in the substantially planar region of the keypad (shown in FIG. 1). The key 300 also has a protruded top edge 322 substantially opposite the indented edge 312. In this embodiment, the protruded top edge 322 has a generally convex shape while the indented bottom edge 312 has a generally concave shape. Various angles and curves can be used to form alternate protruded edges and indented edges. The opposing indented edge 312 and protruded edge 322 allow adjacent keys to “nest” close to each other. The density allowed by the nested keys allows larger key surface areas, which enable users to more easily press the keys and read any labels on the keys.

The key 300 also has other edges, which may be straight, indented, or protruded. In this first preferred embodiment, side edges 314, 316 are slightly indented and foot edges 324, 326 are protruded. As can be seen in FIG. 1, the alternating orientation of each column of keys allows the protruded foot edge 324 of one key to nest against the slightly indented side edge 314 of an adjacent key. Instead of reversing the orientation of the keys in adjacent columns, the columns of keys may maintain the same orientation but be staggered in order to promote a nesting configuration. These configurations and key shapes promote a large key surface area.

In order to promote efficient use of the keypad, switches are aligned substantially underneath the centers of the protruded edges 322, 324, 326. Because hexagonal packing is the most efficient arrangement for sphere packing, preferably the angle 390 formed by the lines 393, 396 between the center of the top edge and the centers of the foot edges is approximately sixty degrees. Depending on the exact arrangement of the switches, and user preferences, the angle 390 is preferably no greater than approximately ninety degrees and no less than approximately forty-five degrees.

Upon the surface of the key 300, telephony labels are placed consistent with the ISO Standard keypad. In this first preferred embodiment, a number is placed in center region 345 on the surface of the key. As with conventional ISO Standard keypads, the number is most prominent on the key surface. In regions 332, 334, 336 of secondary prominence are placed the letters associated with the number in region 345. For example, if a “2” is placed in center region 345, a letter “A” would go in region 332, a letter “B” would go in region 334, and a letter “C” would go in region 336. Of course, the exact regions of secondary prominence can be varied according to design usage. For example, the letters could be placed on the keypad adjacent to the key rather than on the key itself. Thus, the regions of secondary prominence would be on the housing rather than the key itself. By maintaining consistency with the ISO Standard, however, users will find it familiar to locate the telephony numbers, letters, and symbols on the keypad, despite any unusual key shapes.

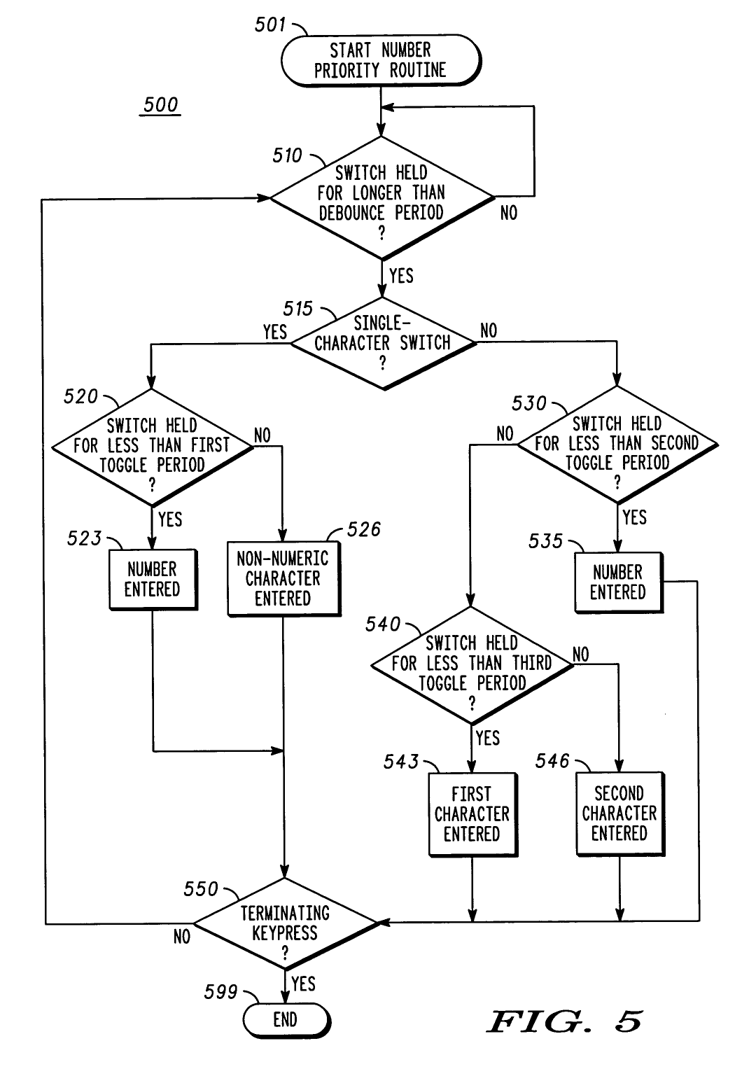

FIG. 4 shows an alternate telephony key 400 according to a second preferred embodiment. An alternate telephony key 400 could be substituted for the telephony keys 151, 152, 153, 154, 155, 156, 157, 158, 159, 161, 162, 163 shown in FIG. 1. In the orientation shown, the key 400 has an indented bottom edge 412 in the substantially planar region of the keypad (shown in FIG. 1). The key 400 also has a protruded top edge 422 substantially opposite the indented edge 412. Various angles and curves can be used to form alternate protruded edges and indented edges. These opposing indented edges 412 and protruded edges 422 allow adjacent keys to “nest” close to each other. The density allowed by the nested keys allows larger key surface areas.

The key 400 also has other edges, which may be straight, indented, or protruded. In this second preferred embodiment, side edges 414, 416 are substantially straight and foot edges 424, 426 are slightly protruded. Analogizing to FIG. 1, the orientation of the keys allows the foot edge 424 of one key to rest against the substantially straight side edge 414 of an adjacent key. This, also, allows a large key surface area.

In order to promote efficient use of the keypad, switches are aligned substantially underneath the centers of the protruded edges 422, 424, 426. Because hexagonal packing is the most efficient arrangement for sphere packing, preferably the angle 490 formed by the lines 493, 496 between the center of the top edge and the centers of the foot edges is approximately sixty degrees. Depending on the exact arrangement of the switches, and user preferences, the angle 490 is preferably no greater than approximately ninety degrees and no less than approximately forty-five degrees.

Upon the surface of the key 400, telephony labels are placed consistent with the ISO Standard keypad. In this second preferred embodiment, a number is placed in center region 445 on the surface of the key. As with ISO Standard keypads, the number is most prominent on the key surface. In regions 432, 434, 436 of secondary prominence are placed the letters associated with the number in region 445. For example, if a “2” is placed in center region 445, a letter “A” would go in region 432, a letter “B” would go in region 434, and a letter “C” would go in region 436. Of course, the exact regions of secondary prominence can be varied according to design usage. For example, the letters could be placed on the keypad adjacent to the key rather than on the key itself. Thus, the regions of secondary prominence would be on the housing rather than the key itself. By maintaining consistency with the ISO Standard, however, users will find it familiar to locate the telephony numbers, letters, and symbols on the keypad shown in FIG. 1, despite any unusual key shapes.

FIG. 5 shows a flow chart 500 for character entry, with a priority on numeric entry, using the keypad shown in FIG. 1. Telephony keys 151, 152, 153, 154, 155, 156, 157, 158, 159, 161, 162, 163 shown in FIG. 1 are used to enter both numeric and non-numeric characters to an electronic device. The start step 501 of the number priority routine can be triggered in a variety of ways. For example, if a user starts typing a number into the keypad using a telephony key, the number priority routine will start. This would occur, for example, when a user is typing a telephone number into a telephone or typing a television channel into a remote controller. Alternately, a user can navigate using softkeys or other non-telephony keys to initiate a number entry routine, such as entering a telephone number into an address book or setting favorite television channels.

If a switch associated with a telephony key is held for less than a debounce period, the number priority routine will disregard the keypress as shown in step 510. For this preferred embodiment, the debounce period is approximately fifty milliseconds. Of course, different debounce periods can be implemented depending on the application of the keypad and user preferences. If a switch associated with a telephony key is held for longer than a debounce period as shown in step 510, the number priority routine will determine whether a single-character switch has been pressed as shown in step 515. FIG. 1 shows two switches that are associated with more than one character. They are the left foot switch of key 157, which is associated with both the letters P and Q, and the right foot switch of key 159, which is associated with both the letters Y and Z. Of course, other switches may be associated with more than one character; however, it is reasonable for there to be a multi-character switch for the letters Q and Z due to the fact that those letters are not included in the ISO Standard keypad arrangement.

If the switch is a single-character switch, step 520 determines when the switch was held for less than the first toggle period. For this preferred embodiment, the first toggle period is approximately one second. Of course, different first toggle periods can be implemented depending on the application of the keypad and user preferences. If the switch was held for less than the first toggle period, a number associated with the switch is entered as shown in step 523. If the switch was held for longer than the first toggle period, a character associated with the switch is entered as shown in step 526. Note that, for each telephony key, three switches are associated with a single number but only a maximum of one switch is associated with a non-numeric character.

If the switch is a multi-character switch as determined in step 515, step 530 determines when the switch was held for less than a second toggle period. For this preferred embodiment, the second toggle period is equal to the first toggle period and is approximately one second. Of course, different second toggle periods can be implemented depending on the application of the keypad and user preferences. If the switch was held for less than the second toggle period, a number associated with the switch is entered as shown in step 535. If the switch was held for longer than the second toggle period, step 540 determines if the switch was held for less than a third toggle period, which is longer than the second toggle period. In this embodiment, the third toggle period is simply twice as long as the second toggle period and about two seconds. If the switch was held for less than the third toggle period, a first character associated with the switch is entered as shown in step 543. If the switch was held for longer than the third toggle period, a second character associated with the switch is entered as shown in step 546. In the preferred embodiment, the second character is the character missing from the ISO Standard keypad arrangement (e.g., Q or Z) while the first character is included in the ISO Standard keypad arrangement.

Unless there is a terminating keypress in step 550, the number priority routine returns to step 510 and prepares to receive additional keypresses. A terminating keypress, such as END or SEND (shown in FIG. 1), causes the number priority routine to end in step 599.

Preferably, this flowchart is implemented in software of the electronic device. As evident from the flow chart 500, the number priority routine allows quick and accurate number entry using the keypad. Non-numeric characters, however, can also be entered by holding a switch for longer then a first toggle period or, under certain conditions, longer than a second toggle period. Although, in this embodiment, the second toggle period is equal to the first toggle period, and the third toggle period is simply twice as long as the second toggle period, the three toggle periods need not be related (other than the third toggle period should be longer than the second toggle period).

FIG. 6 shows a flow chart 600 for character entry, with a priority on non-numeric entry, using the keypad shown in FIG. 1. Telephony keys 151, 152, 153, 154, 155, 156, 157, 158, 159, 161, 162, 163 shown in FIG. 1 are used to enter both numeric and non-numeric characters to an electronic device. The start step 601 of the non-numeric character priority routine can be triggered in a variety of ways. For example, if a user navigates to a browser, short message service, text message service, or address book name application, the non-numeric priority routine will start.

If a switch associated with a telephony key is held for less than a debounce period, the non-numeric character priority routine will disregard the keypress as shown in step 610. For this preferred embodiment, the debounce period is approximately fifty milliseconds. Of course, different debounce periods can be implemented depending on the application of the keypad and user preferences. If a switch associated with a telephony key is held for longer than the debounce period as determined in step 610, the non-numeric character priority routine will determine whether a single-character switch has been pressed as shown in step 615. FIG. 1 shows two switches that are associated with more than one character. They are the left foot switch of key 157, which is associated with both the letters P and Q, and the right foot switch of key 159, which is associated with both the letters Y and Z. Of course, other switches may be associated with more than one character; however, it is reasonable for there to be a multi-character switch for the letters Q and Z due to the fact that those letters are not included in the ISO Standard keypad arrangement.

If the switch is a single-character switch, step 620 determines when the switch was held for less than a first toggle period. For this preferred embodiment, the first toggle period is approximately one second. Of course, different first toggle periods can be implemented depending on the application of the keypad and user preferences. If the switch was held for less than the first toggle period, a non-numeric character associated with the switch is entered as shown in step 623. If the switch was held for longer than the first toggle period, a number associated with the switch is entered as shown in step 626. Note that, for each telephony key, three switches are associated with a single number but only a maximum of one switch is associated with a non-numerical character.

If the switch is a multi-character switch as determined in step 615, step 630 determines when the switch was held for less than a second toggle period. For this preferred embodiment, the second toggle period is equal to the first toggle period and approximately one second. Of course, a different second toggle period can be implemented depending on the application of the keypad and user preferences. If the switch was held for less than the second toggle period, a first character associated with the switch is entered as shown in step 635. If the switch was held for longer than the second toggle period, step 640 determines if the switch was held for less than the third toggle period. If the switch was held for less than the third toggle period, a second character associated with the switch is entered as shown in step 643. If the switch was held for longer than the third toggle period, a number associated with the switch is entered as shown in step 646. In the preferred embodiment, the second character is the character missing from the ISO Standard keypad arrangement (e.g., Q or Z) while the first character is included in the ISO Standard keypad arrangement. Although, in this embodiment, the second toggle period is equal to the first toggle period, and the third toggle period is simply twice as long as the second toggle period, the three toggle periods need not be related (other than the third toggle period should be longer than the second toggle period).

Unless there is a terminating keypress in step 650, the non-numeric priority routine returns to step 610 and prepares to receive additional keypresses. A terminating keypress, such as END or SEND (shown in FIG. 1), causes the non-numeric priority routine to end in step 699.

Preferably, this flowchart is implemented in software of the electronic device. As evident from the flow chart 600, the non-numeric character priority routine allows quick and accurate non-numeric character entry using the keypad. Number characters, however, can also be entered by holding a switch for longer then a first toggle period or, under certain conditions, a second or third toggle period.

Thus, the keypad facilitates alphanumeric character entry while maintaining a reasonable key surface and distance between keys. The keypad also is consistent with the ISO Standard keypad arrangement, which facilitates quick learning and usage of the keypad.

While this disclosure includes what are considered presently to be the preferred embodiments and best modes of the invention described in a manner that establishes possession thereof by the inventor and that enables those of ordinary skill in the art to make and use the invention, it will be understood and appreciated that there are many equivalents to the preferred embodiments disclosed herein and that modifications and variations may be made without departing from the scope and spirit of the invention, which are to be limited not by the preferred embodiments but by the appended claims, including any amendments made during the pendency of this application and all equivalents of those claims as issued.

It is further understood that the use of relational terms such as first and second, top and bottom, and the like, if any, are used solely to distinguish one from another entity, item, or action without necessarily requiring or implying any actual such relationship or order between such entities, items or actions. Some of the inventive functionality and many of the inventive principles are best implemented with or in software programs or instructions. It is expected that one of ordinary skill, notwithstanding possibly significant effort and many design choices motivated by, for example, available time, current technology, and economic considerations, when guided by the concepts and principles disclosed herein will be readily capable of generating such software instructions and programs with minimal experimentation. Therefore, further discussion of such software, if any, will be limited in the interest of brevity and minimization of any risk of obscuring the principles and concepts according to the present invention.

1. An electronic device with a keypad on a substantially planar surface comprising:
a first key with
an indented edge in the substantially planar surface,
a first protruded edge in the substantially planar surface,
a first alphanumeric label associated with the first key, and
a second alphanumeric label associated with the first protruded edge of the first key;
a second key with a protruded edge in the substantially planar surface adjacent to the indented edge of the first key; and
a third key with an indented edge in the substantially planar surface adjacent to the first protruded edge of the first key.

2. An electronic device according to claim 1 wherein the first key further comprises:
a second protruded edge in the substantially planar surface;
a third protruded edge in the substantially planar surface; and
an angle formed by lines between a center of the first protruded edge and centers of the second protruded edge and the third protruded edge is greater than approximately forty-five degrees.

3. An electronic device according to claim 2 wherein the angle is less than approximately ninety degrees.

4. An electronic device according to claim 1 further comprising:
a priority routine that enters a character associated with the first alphanumeric label when the first key is held for less than a first toggle period.

5. An electronic device according to claim 4 wherein the first alphanumeric label represents a number.

6. An electronic device according to claim 4 wherein the priority routine enters a character associated with the second alphanumeric label when the first key is held for more than the first toggle period.

7. An electronic device according to claim 6 wherein the second alphanumeric label represents a non-numeric character.

8. An electronic device according to claim 7 wherein the second alphanumeric label represents a letter.

9. An electronic device according to claim 7 wherein the second alphanumeric label represents a space.

10. An electronic device according to claim 4 wherein the priority routine enters a character associated with the second alphanumeric label when the first key is held for less than a second toggle period that is greater than the first toggle period.

11. An electronic device according to claim 10 wherein the priority routine enters a character associated with a third alphanumeric label when the first key is held for more than the second toggle period.

12. A keypad, on a surface having a substantially planar region, comprising:
a first key with
an indented edge in the substantially planar region,
a first protruded edge in the substantially planar region,
a first alphanumeric label associated with the first key, and
a second alphanumeric label associated with the first protruded edge of the first key;
a second key with a protruded edge in the substantially planar region proximate to the indented edge of the first key; and
a third key with an indented edge in the substantially planar region proximate to the first protruded edge of the first key.

13. A keypad according to claim 12 wherein the first key further comprises:
a second protruded edge in the substantially planar region;
a third protruded edge in the substantially planar region; and
an angle formed by lines between a center of the first protruded edge and centers of the second protruded edge and the third protruded edge is greater than approximately forty-five degrees.

14. A keypad according to claim 13 wherein the angle is less than approximately ninety degrees.

15. A keypad according to claim 13 further comprising:
a fourth key with an indented edge in the substantially planar region proximate to the second protruded edge of the first key.

16. A keypad according to claim 15 wherein the first key, the second key, the third key, and the fourth key have approximately the same shape.

17. A keypad according to claim 12 wherein the first key, the second key, and the third key have approximately the same shape.

18. A keypad according to claim 12 comprising:
a first label associated with the first key.

19. A keypad according to claim 18 wherein the first label represents a numeric character.

20. A keypad according to claim 18 further comprising:
a second label associated with the first key.

21. A keypad according to claim 20 wherein the second label represents a non-numeric character.
